(19) United States
(12) Patent Application Publication
(10) Pub. No.: US 2011/0002186 A1
(43) Pub. Date: Jan. 6, 2011

(54) SECURE ELECTRICALLY PROGRAMMABLE FUSE AND METHOD OF OPERATING THE SAME

(75) Inventors: Michael S. Buonpane, Easton, PA (US); Richard P. Martin, Macungie, PA (US); Richard Muscavage, Gilbertsville, PA (US); Scott A. Segan, Allentown, PA (US); Eric P. Wilcox, Allentown, PA (US)

Correspondence Address: HITT GAINES, PC;LSI Corporation, PO BOX 832570, RICHARDSON, TX, 75083, US

(73) Assignee: LSI Corporation, Milpitas, CA (US)

(21) Appl. No.: 12/496,624

(22) Filed: Jul. 1, 2009

(51) Int. Cl. G11C 17/18

(52) U.S. Cl. 365/225.7

(57) ABSTRACT

An electrically programmable fuse, a method of operating the same and an integrated circuit (IC) incorporating the fuse or the method. In one embodiment, the fuse includes: (1) at least one fuse element configured to be programmed with contents and (2) an inhibitor coupled to the at least one fuse element and configured to be activated to inhibit subsequent reprogramming of the at least one fuse element.

### TECHNICAL FIELD

This application is directed, in general, to encryption security key security and, more specifically, to a secure electrically programmable fuse (eFuse) and method of operating the same.

### BACKGROUND

eFuses allow dynamic, real-time programming of integrated circuits (ICs). eFuses find particular use in customizing ICs after the manufacturing process is complete, for example, to store cryptographic security keys. eFuses make it possible to program each IC with a different security key. (An “eFuse,” as that term is used herein, denotes one or more eFuse elements, allowing the eFuse respectively to store one or more bits of information.)

Unfortunately, problems can arise when attempting to reprogram an eFuse. An authorized party unknowingly trying to reprogram an eFuse may produce unpredictable results due to the manner in which the eFuse is programmed. An unauthorized party may deliberately disable security by reprogramming an eFuse with a known number to make the cryptographic algorithm easier to defeat or may try to read the eFuse directly (via external pins) to obtain the security key. The eFuse could be isolated from the pins to make it externally unreadable, however it would then be externally unreadable for all purposes, including the valid purpose of verifying its originally-programmed contents.

An eFuse is typically programmed by applying a relatively high voltage programming voltage (VDDQ), normally 2.5V, along with chip select, clock and program pin signals. On the rising edge of the clock signal if the program pin is active “1,” the fuse is blown, and if the program pin signal is inactive “0,” the fuse is not blown. By default, the eFuse is not entirely blown. Thus, an unprogrammed fuse reads all zeros. To read an eFuse, the VDDQ is brought to 0V, the chip select signal is made active, the program pin signal is made inactive, and on the falling edge of the clock, the data appears on the output of the eFuse. The eFuse can be programmed before the wafer is sawed into dice (“singulated”) or before or after the dice are packaged, as long as VDDQ can be applied.

### SUMMARY

One aspect provides an eFuse. In one embodiment, the eFuse includes: (1) at least one eFuse element configured to be programmed with contents and (2) an inhibitor coupled to the at least one eFuse element and configured to be activated to inhibit subsequent reprogramming of the at least one eFuse element.

Another aspect provides a method of operating an eFuse. In one embodiment, the method includes: (1) programming the eFuse with contents and (2) thereafter activating an inhibitor to inhibit reprogramming of the eFuse.

Yet another aspect provides an IC. In one embodiment, the IC includes: (1) a substrate, (2) functional circuitry associated with the substrate and (3) an eFuse coupled to the functional circuitry and having: (3a) at least one eFuse element configured to be programmed with contents, (3b) an inhibitor coupled to the at least one eFuse element and configured to be activated to inhibit subsequent reprogramming of the eFuse and (3c) a manipulator coupled to the at least one eFuse element and configured to manipulate the contents retrieved from the at least one eFuse element to yield manipulated contents and provide the manipulated contents to the functional circuitry.

### BRIEF DESCRIPTION

Reference is now made to the following descriptions taken in conjunction with the accompanying drawings, in which:

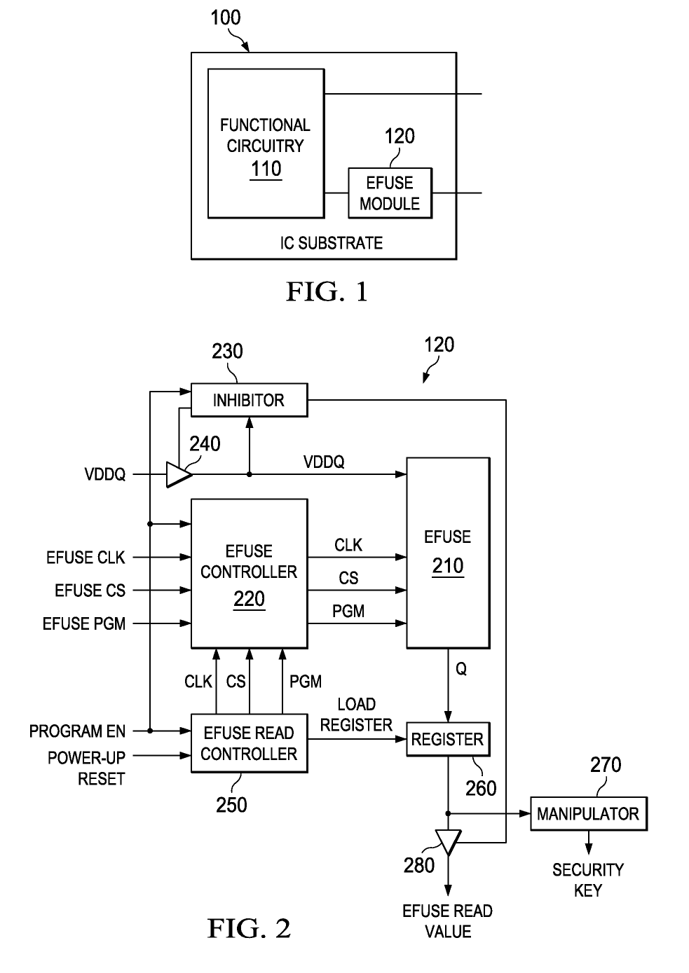

FIG. 1 is a highly schematic plan view of an IC into which an eFuse may be integrated;

FIG. 2 is a block diagram of one embodiment of the eFuse module of FIG. 1; and

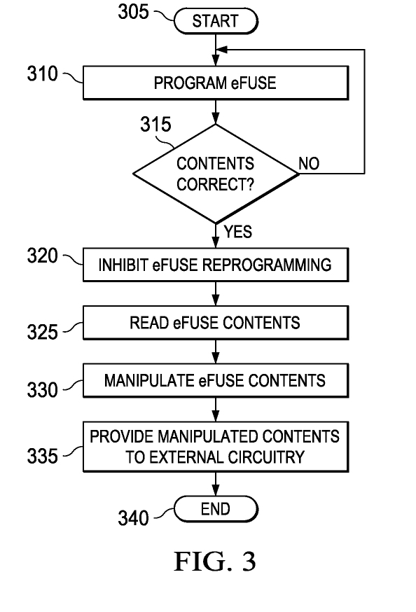

FIG. 3 is a flow diagram of one embodiment of a method of operating an eFuse.

### DETAILED DESCRIPTION

Described herein are various embodiments of an eFuse and method of operation thereof by which, once an eFuse has been programmed (colloquially, “burnt”), the contents of the eFuse cannot be altered by rewriting it. In general, the various embodiments increase the likelihood that the contents of the eFuse will remain secure after having been programmed. In certain of the embodiments described herein, an “inhibitor” is provided whereby, after the eFuse has been programmed, the inhibitor can be employed to prevent the eFuse from being reprogrammed. In certain other of the embodiments, the contents of the eFuse are not directly used as the security key. Instead, the contents are provided to a “manipulator” that transforms the contents into the security key. The contents of the eFuse can thus be employed in some manner (e.g., cryptography) without the need to expose the contents themselves.

It is generally expected that after programming the eFuse, its contents are read to ensure that the programming was performed successfully and the contents are therefore free of defects. It is recognized that the need to verify the contents of the eFuse after programming often eliminated conventional eFuses as a candidate for cryptographic applications. The inhibitor can provide a mechanism by which the contents of the eFuse may be verified and thereafter protected against being reprogrammed. The manipulator can provide a mechanism by which the contents may be verified and thereafter protected against being directly read.

FIG. 1 is a highly schematic plan view of an IC into which an eFuse may be integrated. FIG. 1 shows an IC substrate 100, which may be composed of any conventional or later-developed substrate material. The IC substrate 100 functions as a foundation in which or on which is fabricated integrated circuitry, including electronic devices (e.g., transistors, diodes and capacitors) and interconnecting conductors (e.g., “metallization”). FIG. 1 shows functional circuitry 110, which represents integrated circuitry located in or on the IC substrate 100 and typically forming the majority of an IC. The functional circuitry 110 may include analog circuitry, digital logic such as a processor or controller, digital memory such as random-access, read-only or flash memory or any other conventional or later-developed circuitry as may be appropriate for a given application. The functional circuitry 110 may be fabricated using any conventional or later-developed fabrication process or scale. The functional circuitry 110 includes at least one unreferenced external conductor (colloquially, a “pin”) that allows electrical contact to be made between the functional circuitry 110 and external circuitry (not shown).

An eFuse module 120 is coupled to the functional circuitry 110. The illustrated embodiment of the eFuse module 120 likewise includes at least one unreferenced external conductor that allows electrical contact to be made between the eFuse module 120 and external circuitry (not shown). As will be described more particularly in conjunction with FIG. 2, the eFuse module 120 includes an eFuse and control circuitry configured to write data to, and read data from, the eFuse. Various embodiments of the eFuse module 120 also include either or both of various embodiments of the aforementioned inhibitor and manipulator.

FIG. 2 is a block diagram of one embodiment of the eFuse module 120 of FIG. 1. The illustrated embodiment of the eFuse module 120 includes an eFuse 210, an eFuse controller 220, an inhibitor 230, a first buffer 240, an eFuse read controller 250, a register 260, a manipulator 270 and a second buffer 280.

As described above, the eFuse 210 includes one or more eFuse elements (not shown), each of which being configured to store one bit of data. In embodiments in which the eFuse 210 has more than one eFuse element, the eFuse elements cooperate to store multiple bits of data in parallel, perhaps logically segmented into bytes, words or other conventional or later-developed data structures.

The eFuse controller 220 is configured to determine if a read or write operation to the eFuse 210 is to occur. In the illustrated embodiment, if program enable (EN) is active, a write operation is selected; if EN is inactive, a read operation is selected. When a write operation is selected, the eFuse controller 220 passes externally received signals, i.e., clock (CLK), chip select (CS) and program (PGM), to the eFuse 210. When a read operation is selected, the eFuse controller 220 receives CLK, CS and PGM from the eFuse read controller 250.

As stated above, the inhibitor 230 addresses the problem of unauthorized reprogramming of the eFuse 210. In the illustrated embodiment, the inhibitor 230 is configured to be activated after the eFuse 210 is initially programmed. In a more specific embodiment, the inhibitor 230 is configured to be activated after the contents of the eFuse 210 are verified as being correct. Activating the inhibitor 230 after verification is performed allows reprogramming to occur until correct results are produced. Once the inhibitor 230 is activated, subsequent reprogramming (including unauthorized reprogramming) is inhibited.

In the illustrated embodiment, the inhibitor 230 includes a single eFuse element (not shown), allowing the inhibitor 230 to achieve binary states. In this embodiment, the inhibitor 230 initially has a one state. In the illustrated embodiment, the one state, along with CLK, is provided to the first buffer 240, closing it and allowing a nonzero VDDQ (a relatively high voltage in the illustrated embodiment) to be applied to the eFuse 210 on at least one subsequent CLK edge (e.g., the next falling edge). Once the inhibitor 230 is activated, it achieves a zero state, opening the first buffer 240 and preventing a nonzero VDDQ to be applied to the eFuse 210 during subsequent CLK edges. Thus, if someone attempts to reprogram the eFuse 210 after the inhibitor 230 is activated, VDDQ remains at 0V at the eFuse 210, and reprogramming is inhibited. As can be seen in FIG. 2, the first buffer 240, once opened, further inhibits a nonzero VDDQ from being provided to the inhibitor 230 itself, thereby inhibiting its own reprogramming.

An alternative embodiment substitutes an unclocked switch for the first buffer 240, preventing a nonzero VDDQ from being applied to the eFuse 210 upon its opening. In a more specific embodiment, the switch, once opened, further inhibits VDDQ from being provided to the inhibitor 230.

As stated above, the manipulator 270 addresses the problem of unauthorized reading of the contents of the eFuse 210. One of the methods unauthorized persons (colloquially, “hackers”) use to obtain the contents of the eFuse 210 is to observe which eFuse elements have been blown. More specifically, the manipulator 270 is employed to create a security key, thereby preventing the contents of the eFuse from having to leave the eFuse module 120.

On a power-up reset, the eFuse read controller 250 asserts a “load register” signal to the register 260, causing the contents of the eFuse 210 to be copied into the register 260. The eFuse 210 may then be powered down. In the embodiment of FIG. 2, the eFuse read controller 250 causes the contents of the eFuse to be copied (via “Q”) to the register 260 only if EN is inactive.

The illustrated embodiment of the manipulator 270 is configured to employ an arithmetic formula or algorithm to transform the value read from the eFuse 210 into the security key. The eFuse 210 can still be read directly to verify its contents via “eFuse read value” in FIG. 2. However, as FIG. 2 shows, “eFuse read value” is disabled by the second buffer 280 when the inhibitor 230 is activated. The actual contents of the eFuse 210 remain hidden with respect to “security key” of FIG. 2.

In the illustrated embodiment, only “security key” is externally accessible via a pin of the IC; “eFuse read value” is not. In an alternative embodiment, both “security key” and “eFuse read value” are externally accessible via pins of the IC. Again, however, the second buffer 280 disables “eFuse read value” when the inhibitor 230 is activated.

FIG. 3 is a flow diagram of one embodiment of a method of operating an eFuse. The method begins in a start step 305. In a step 310, the eFuse is programmed with contents (i.e., one or more bits of information, typically in a prescribed order). In a decisional step 315, it is determined whether or not the contents were programmed correctly. If not, the eFuse is reprogrammed by repeating the step 310. The contents are tested again in the step 315. Steps 310, 315 may be repeated until the eFuse contents are programmed correctly or the eFuse is determined to be faulty.

Once the contents are determined to be programmed correctly, reprogramming of the eFuse is inhibited in a step 320. In a step 325, which may be carried out while an end-user is operating an IC, the contents of the eFuse are read. In a step 330, the contents are manipulated, for example by employing a mathematical formula or algorithmic process to transform the contents in any conceivable way. As a result, the original contents are transformed into manipulated contents, preferably such that the original contents are less discoverable and remain more secure. In a step 335, the manipulated contents are provided to external circuitry (e.g., the functional circuitry 110 of FIG. 1 or circuitry located outside of the IC substrate 100 of FIG. 1). The method ends in an end step 340.

Those skilled in the art to which this application relates will appreciate that other and further additions, deletions, substitutions and modifications may be made to the described embodiments.

What is claimed is:

1. An electrically programmable fuse, comprising:
at least one fuse element configured to be programmed with contents; and
an inhibitor coupled to said at least one fuse element and configured to be activated to inhibit subsequent reprogramming of said at least one fuse element.

2. The fuse as recited in claim 1 further comprising:
a register configured to store said contents retrieved from said at least one fuse element; and
a manipulator coupled to said register and configured to manipulate said contents to yield manipulated contents and provide said manipulated contents to external circuitry.

3. The fuse as recited in claim 2 wherein said manipulator is further configured to apply to said contents one of:
a mathematical formula, and
an algorithmic process.

4. The fuse as recited in claim 2 wherein said register is further configured to allow said contents to be determined to be correct before said inhibitor is activated.

5. The fuse as recited in claim 1 wherein said at least one fuse element is further configured to be reprogrammed before said inhibitor is activated.

6. The fuse as recited in claim 1 wherein said contents comprises multiple bits of information.

7. The fuse as recited in claim 1 wherein said fuse is embodied in an integrated circuit together with functional circuitry.

8. A method of operating an electrically programmable fuse, comprising:
programming said fuse with contents; and
thereafter activating an inhibitor to inhibit reprogramming of said fuse.

9. The method as recited in claim 8 further comprising:
retrieving said contents from said fuse;
manipulating said contents to yield manipulated contents; and
providing said manipulated contents to external circuitry.

10. The method as recited in claim 9 wherein said manipulating comprises applying to said contents one of:
a mathematical formula, and
an algorithmic process.

11. The method as recited in claim 8 further comprising determining whether said contents are correct before said activating.

12. The method as recited in claim 8 further comprising reprogramming said fuse before said activating.

13. The method as recited in claim 8 wherein said contents comprises multiple bits of information.

14. The method as recited in claim 8 wherein said fuse is embodied in an integrated circuit together with functional circuitry.

15. An integrated circuit, comprising:
a substrate;
functional circuitry associated with said substrate; and
an electrically programmable fuse coupled to said functional circuitry and including:
at least one fuse element configured to be programmed with contents,
an inhibitor coupled to said at least one fuse element and configured to be activated to inhibit subsequent reprogramming of said fuse, and
a manipulator coupled to said at least one fuse element and configured to manipulate said contents retrieved from said at least one fuse element to yield manipulated contents and provide said manipulated contents to said functional circuitry.

16. The circuit as recited in claim 15 further comprising a register coupled between said at least on fuse element and said manipulator and configured to store said contents retrieved from said at least one circuit element.

17. The circuit as recited in claim 15 wherein said manipulator is further configured to apply to said contents one of:
a mathematical formula, and
an algorithmic process.

18. The circuit as recited in claim 16 wherein said register is further configured to allow said contents to be determined to be correct before said inhibitor is activated.

19. The circuit as recited in claim 15 wherein said at least one circuit element is further configured to be reprogrammed before said inhibitor is activated.

20. The circuit as recited in claim 15 wherein said contents comprises multiple bits of information.
